(19) United States
(12) Patent Application Publication
(10) Pub. No.: US 2011/0024177 A1
(43) Pub. Date: Feb. 3, 2011

(54) METHOD FOR SOLDERING ELECTRONIC COMPONENTS OF CIRCUIT BOARD AND CIRCUIT BOARD STRUCTURE THEREOF

(75) Inventors: Hung Tao Wong, Taipei (TW); Chung Yang Wu, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Inventec Corporation, Taipei (TW)

(21) Appl. No.: 12/511,161

(22) Filed: Jul. 29, 2009

(51) Int. Cl. H05K 1/11; H05K 3/34

(52) U.S. Cl. 174/262; 29/840

(57) ABSTRACT

A method for soldering electronic components of a circuit board and a circuit board structure thereof are presented. The method includes providing a circuit board first; disposing at least one solder hole and at least one heat collecting hole on the circuit board, in which the heat collecting hole is disposed around the solder hole to form a heat collecting area; extending a pin of an electronic component into the solder hole; filling a solder within the solder hole through a soldering process; and keeping heat of the solder in the heat collecting area by the heat collecting hole. Thus, the pin of the electronic component within the solder hole is successfully combined with the solder.

### BACKGROUND OF THE INVENTION

1. Field of Invention

The present invention relates to a means of soldering electronic components, and more particularly to a method for soldering electronic components of a circuit board and a circuit board structure thereof.

2. Related Art

Currently, in a wave soldering process, a high-temperature liquid solder is filled in a plated through hole (PTH) on a printed circuit board, such that pins of an electronic component extending into the PTH and the printed circuit board are combined, so as to achieve a purpose that the electronic component is secured on and electrically conducted with the circuit board.

In the wave soldering process, a turbulent wave is usually used to inject the high-temperature liquid solder upward from a lower surface of the printed circuit board in the PTH, such that the PTH is filled with the solder, and a solder joint is formed after the solder covers the pins of the electronic component. Subsequently, excessive solder on the lower surface of the printed circuit board is then cleaned by using a laminar wave, so as to prevent the short circuit among the pins of the electronic component, and secure the electronic component on the circuit board.

Moreover, a solder used in the common wave soldering process may be categorized into lead solder and leadless solder. The lead solder has characteristics of a low melting point (about 183° C.) and a high surface tension. Therefore, when the solder is injected in the PTH of the printed circuit board by a turbulent wave, the lead solder is not easy to solidify on the lower surface of the printed circuit board, and will also be filled in the whole PTH easily.

However, to meet the environment requirements, the current solder usually contains no lead. In the situation that the solder does not contain lead, as the melting point of a leadless solder is higher (about 217 to 219° C.), some problems will occur in the wave soldering process.

For example, a usual wave soldering device mainly includes a conveyor belt, a solder bath, a first heater, and a second heater. The conveyor belt is configured to convey a printed circuit board. The solder bath is disposed below the conveyor belt, and the solder bath is filled with a melted high-temperature liquid leadless solder. In addition, the solder bath includes a turbulent nozzle and a laminar nozzle. The first heater and the second heater are disposed at sides of the solder bath, and are disposed above and below the conveyor belt respectively.

When the printed circuit board is conveyed from the conveyor belt to the solder bath, the printed circuit board will be first heated by the first heater and the second heater, such that an upper surface and lower surface of the printed circuit board are preheated a predetermined temperature respectively. When the printed circuit board is conveyed above the solder bath, the turbulent nozzle will inject the liquid leadless solder in the solder bath upward to the PTH containing the electronic component pins. Next, the laminar nozzle will inject the liquid leadless solder in the solder bath to the lower surface of the printed circuit board, so as to clean excessive leadless solder on the lower surface of the printed circuit board.

However, as the melting point (solidification point) of the leadless solder is relatively high, after the high-temperature liquid leadless solder is injected upward into the PTH of the printed circuit board by the turbulent nozzle, because the printed circuit board is unable to be evenly heated in the preheating process, or due to the influence caused by the thickness of the printed circuit board, a position of the PTH of the printed circuit board close to the upper surface often cannot reach a soldering temperature, such that the temperature distribution on the upper and lower surfaces of the PTH is uneven.

Thus, the liquid leadless solder may easily be solidified before the liquid leadless solder upwardly fills the whole PTH completely, such that solder defects are generated between the pins of the electronic component and the PTH. Therefore, the specification of the through hole solder fill in IPC international test standards (that is, the solder needs to fill more than 75% of the PTH) is not satisfied.

Meanwhile, excessive leadless solder will be massively solidified below the pins of the electronic component. When the PTH is conveyed above the laminar nozzle, as a movement distance between the turbulent nozzle and the laminar nozzle is too long, the temperature of the lower surface of the printed circuit board has already become very low. Because of the low temperature and the factors that the melting point (solidification point) of the leadless solder is relatively high and the surface tension is relatively small, the liquid leadless solder injected from the laminar nozzle is unable to clean the excessive leadless solder, and will be solidified again on the lower surface of the printed circuit board due to the low temperature of the lower surface of the printed circuit board, causing short circuit among the pins of the electronic component.

In addition, in the process for filling the leadless solder, heat of the leadless solder will be easily dissipated from the PTH to outside the circuit board, such that the heat energy is not concentrated within the PTH. Thus, the solder will be solidified too fast, such that the solder is unable to fill in the PTH completely, resulting in poor electrical contact.

Therefore, in the manufacturing and production of printed circuit boards, the circuit boards having solder defects must be reworked. Correspondingly, the overall production cost of the circuit boards will be significantly increased, and unnecessary rework time will be consumed. Therefore, it is an urgent subject to be solved for those skilled in the art to ensure that the solder fills in the PTH of the printed circuit board completely, so as to increase the soldering yield of the printed circuit board and electronic components.

### SUMMARY OF THE INVENTION

A conventional leadless solder has a high melting point, and a circuit board is not evenly heated in a preheating process, or is influenced by a thickness of the circuit board. Therefore, a position of a plated through hole (PTH) of the circuit board close to an upper surface cannot reach a soldering temperature, causing a problem that the leadless solder is solidified before the PTH is completely filled. In view of the problem, the present invention provides a method for soldering electronic components of a circuit board and a circuit board structure thereof.

The method for soldering electronic components of a circuit board of the present invention is as follows: providing a circuit board, in which the circuit board has a plurality of wire layers and is disposed with at least one solder hole and at least one heat collecting hole, the solder hole and the wire layer are electrically conducted, the heat collecting hole is disposed around the solder hole to form a heat collecting area, and the heat collecting hole and the plurality of wire layers are non-electrically conducted; disposing at least one electronic component on the circuit board, in which a pin of the electronic component extends into the solder hole of the circuit board; performing a soldering process on the circuit board, such that a solder enters the solder hole, and keeping heat of the solder in the heat collecting area by the heat collecting hole, such that the pin of the electronic component located in the solder hole is combined with the solder.

The circuit board structure of the present invention is formed by soldering a solder and at least one pin of at least one electronic component. The circuit board structure comprises a board body, at least one solder hole, and at least one heat collecting hole. The board body has a plurality of wire layers stacked with each other. The solder hole passes through the board body and is electrically conducted with the plurality of wire layers. The pin of the electronic component extends into the solder hole. The heat collecting hole is disposed around the solder hole to form a heat collecting area. The heat collecting hole and the plurality of wire layers are non-electrically conducted. When the solder is disposed within the solder hole, heat of the solder is kept in the heat collecting area by the heat collecting hole, such that the pin of the electronic component is combined with the solder.

The effects of the present invention are as follows: at least one penetrating or non-penetrating heat collecting hole is disposed around the solder hole, and a heat collecting area is formed by the heat collecting hole surrounding the solder hole; when the solder is filled in the solder hole, the heat of the solder is kept in the heat collecting area by the heat collecting hole, such that the heat within the solder hole is kept stable, so as to ensure that the solder hole is filled with the solder and is combined with the pin of the electronic component.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a manufacturing process according to an embodiment of the present invention;

FIGS. 2A to 2C are schematic views of steps according to an embodiment of the present invention;

FIG. 3 is a schematic top view according to an embodiment of the present invention;

FIG. 4 is a schematic sectional view according to another embodiment of the present invention; and

FIG. 5 is a schematic sectional view according to still another embodiment of the present invention.

### DETAILED DESCRIPTION OF THE INVENTION

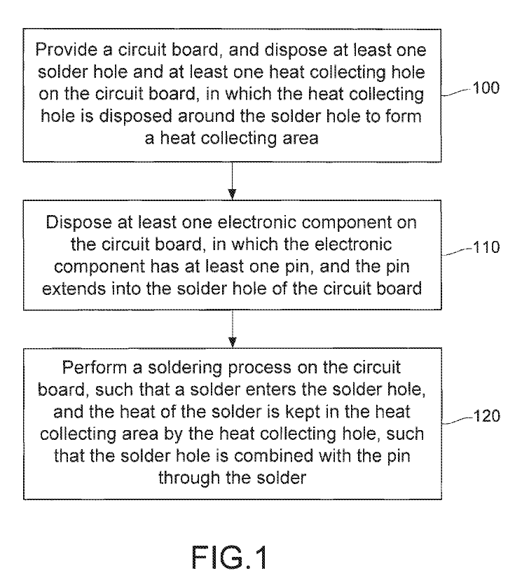

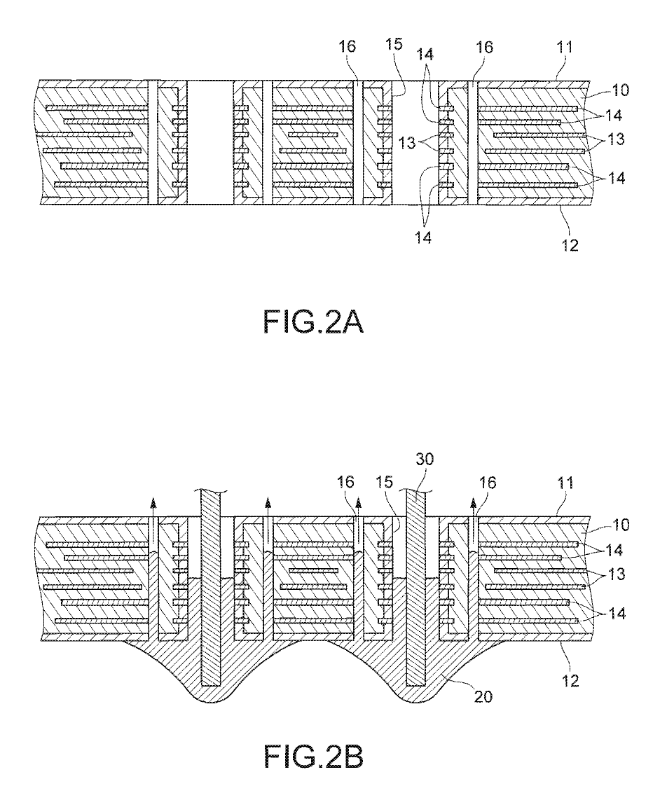

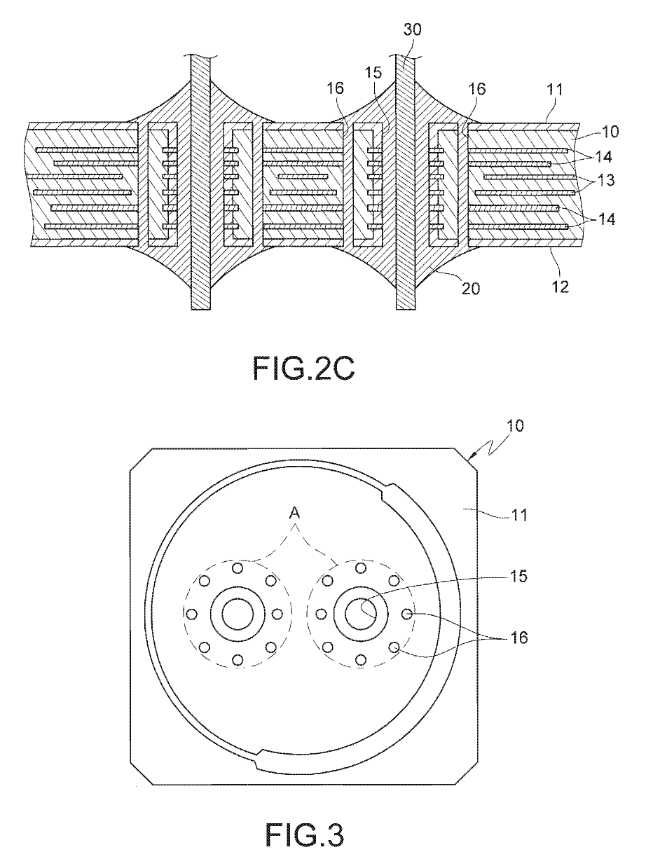

FIGS. 1 and 2A to 2C are a schematic view of a manufacturing process and schematic views of steps according to an embodiment of the present invention respectively.

As shown in FIGS. 1 and 2A, a circuit board is provided first, and at least one solder hole 15 and at least one heat collecting hole 16 are disposed on the circuit board, and the heat collecting hole 16 is disposed around the solder hole 15 to form a heat collecting area A (Step 100).

The circuit board has a board body 10, and an upper surface 11 and a lower surface 12 are disposed respectively on the two opposite sides of the board body 10. A plurality of wire layers 13 stacked with each other and at least one ground layer 14 are disposed in a structure between the upper and lower surfaces 11, 12 of the board body 10. The wire layers 13 are formed of a plurality of power lines, which is a conventional art, and will not be described here.

Moreover, at least one solder hole 15 passes through the upper and lower surfaces 11, 12 of the board body 10, and at least one heat collecting hole 16 is disposed around the solder hole 15. In addition, a plurality of heat collecting holes 16 may be further formed on the board body 10, and the plurality of heat collecting holes 16 surrounds the solder hole 15 respectively in a geometric arrangement, such that a heat collecting area A (indicated by A in FIG. 3) is formed around the solder hole 15 with the heat collecting holes 16.

Moreover, the solder hole 15 is electrically conducted with the wire layers 13 and the ground layer 14 respectively. In addition, the heat collecting holes 16 are only electrically conducted with the ground layer 14, and are non-electrically conducted with the wire layers 13.

In the embodiment of the present invention, the heat collecting holes 16 are penetrating holes, but are not limited thereto. Additionally, the solder hole 15 may be a plated through hole (PTH). A metal coating (not shown) is disposed on an inner surface of the solder hole 15, and the metal coating is electrically conducted with the wire layers 13 and the ground layer 14. However, only a preferred embodiment is described in the above, and the present invention is not limited thereto.

Moreover, when the board body 10 is disposed with the heat collecting holes 16, the heat collecting holes 16 are arranged around the solder hole 15. Specifically, the heat collecting holes 16 surround the solder hole 15 in a geometric shape, and the geometric shape may be a circle, a triangle, a rectangle, or a polygon. In the embodiment of the present invention, the plurality of heat collecting holes 16 surrounds the solder hole 15 in a circle arrangement (as shown in FIG. 3). However, the circle arrangement of the heat collecting holes 16 is only for describing a preferred embodiment, and the present invention is not limited thereto.

The structure design that the heat collecting holes 16 surround the solder hole 15 enables the heat (hot air) generated by the solder of the high-temperature liquid to be concentrated at the plurality of heat collecting holes 16. A heat collecting area A is formed on the board body 10 through the surrounding shape of the plurality of heat collecting holes 16.

As shown in FIGS. 1 and 2B, at least one electronic component is disposed on the circuit board. The electronic component has at least one pin 30, and the pin 30 extends into in the solder hole 15 of the circuit board (Step 110). A soldering process is performed on the circuit board, such that a solder 20 enters the solder hole 15, and the heat of the solder 20 is kept in the heat collecting area A by the heat collecting holes 16, such that the solder hole 15 is combined with the pin 30 through the solder 20 (Step 120).

Thus, a preheating process is performed on the circuit board first, enabling that the hot air passes through the solder hole 15 and the plurality of heat collecting holes 16 surrounding the solder hole 15, and that the solder hole 15 and the heat collecting holes 16 are evenly heated. As such, each solder hole 15 and heat collecting hole 16 can reach a temperature high enough for filling the solder, for example, 230° C., 260° C. or 280° C. However, the temperature of the preheating process on the circuit board is not limited thereto.

Next, the melted solder 20 is driven upward by a motor pump to form a turbulent wave through a wave soldering process, and the solder 20 enters the solder hole 15 of a lower surface of the board body 10 through a pressure from bottom to top.

In addition, an aperture of the heat collecting holes 16 is designed smaller than the aperture of the solder hole 15. In such a manner, through a siphon action of the heat collecting holes 16, the high-temperature liquid solder 20 enters the inside of the heat collecting holes 16, or the hot air carried by the solder 20 enters the inside of the heat collecting holes 16. In other words, in the embodiment, the solder 20 may enter the plurality of heat collecting holes 16, or the hot air carried by the solder 20 may enter the heat collecting holes 16. The aperture of the heat collecting holes 16 is designed smaller than that of the solder hole 15, such that the solder 20 flows upward in the heat collecting holes 16 at a higher speed than the speed of the solder 20 within the solder hole 15, ensuring that the heat of the solder 20 enters the heat collecting holes 16 first, and is kept in the heat collecting area A by the heat collecting holes 16.

Thus, by filling the high-temperature liquid solder 20 in the solder hole 15 and the heat collecting holes 16 at the same time, the heat collecting holes 16 having a small aperture drive the solder 20 upward at a high speed. By contrast, in the solder hole 15 having a larger aperture, the upward speed of the solder 20 is relatively low.

For example, the aperture of the solder hole 15 of the board body 10 is large, so the solder 20 rises slowly within the solder hole 15. Also, as a melting point of a usual leadless solder is about 220° C., the solder is easily influenced by a low temperature on the upper surface 11 of the board body 10 (possibly because the circuit board is not evenly heated in the preheating process, or an upper surface position of the solder hole does not reach a soldering temperature due to the thickness of the circuit board), and is solidified because of the low temperature when it rises within the solder hole 15. Thus, the filling rate of the solder 20 within the solder hole 15 cannot meet the standard (that is, the solder must fill more than 75% of the solder hole), resulting in problems such as solder defects or insufficient solder of the pin 30 in the solder hole 15 of the electronic component.

Thus, in the method for soldering electronic components and the circuit board structure thereof according to the present invention, the solder 20 may rise quickly through the heat collecting holes 16 having a relatively small aperture, and the heat collecting holes 16 are filled with the heat generated by the solder 20 in advance. At the same time, when the solder 20 rises within the heat collecting holes 16, a preheating temperature may be first provided to the solder hole 15, such that the temperature within the solder hole 15 is kept close to that of the solder 20, which especially solves the low temperature problem of the solder hole 15 close to the upper surface 11 of the board body 10. The solder 20 within the solder hole 15 continues to rise through the preheating temperature, ensuring that the solder 20 fills the inside of the solder hole 15 and covers the pin 30 of the electronic component within the solder hole 15.

It is to be noted that the plurality of heat collecting holes 16 is disposed surrounding the solder hole 15. The heat of the solder 20 may be kept in the heat collecting area A by the plurality of heat collecting holes 16. Through the heat collecting area A, the solder hole 15 stays in a stable high-temperature soldering state, avoiding the problem that the solder 20 is solidified when rising within the solder hole 15.

After the solder 20 is cooled and solidified, the pin 30 of the electronic component and the solder hole 15 may be combined and secured to each other through the solder 20, such that the electronic component is fixed on the board body 10, so as to complete the soldering of the pin 30 of the electronic component.

In addition, after the solder hole 15 is filled with the solder 20, the plurality of wire layers 13 and the ground layer 14 of the board body 10 are electrically conducted with the solidified solder 20, and are then electrically connected to the pin 30 of the electronic component through the solder 20, such that the electronic component transmits a signal to the wire layers 13 or the ground layer 14 through the pin 30. The solder 20 solidified within the heat collecting hole 16 electrically contacts the ground layer 14, and the heat collecting holes 16 are away from the wires of the wire layers 13. Thus, the heat collecting holes 16 and the wires of the wire layers 13 will not be electrically conducted, so as to prevent short circuit of the wire layers 13 inside the board body 10 caused by the heat collecting holes 16.

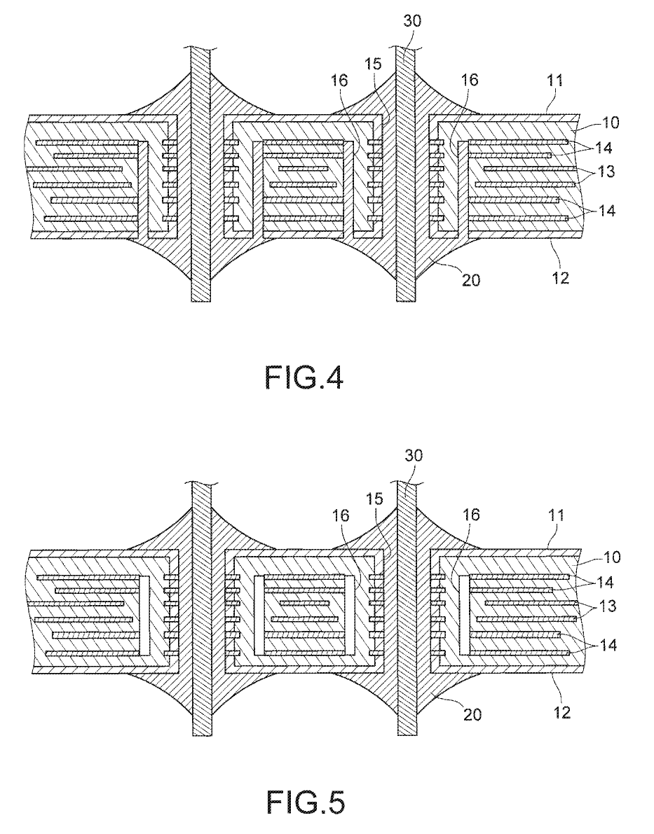

FIG. 4 is a schematic sectional view according to another embodiment of the present invention. The specific implementation is substantially the same as the embodiment above, and only the difference is illustrated in the following. In the embodiment above, the heat collecting holes 16 are through holes passing through the upper and lower surfaces 11 and 12 of the board body 10. In this embodiment, the heat collecting holes 16 are designed as blind hole structures, and are disposed on the lower surface 12 of the board body 10, such that the heat collecting holes 16 do not penetrate the upper surface 11 of the board body 10. In such a manner, the heat collecting holes 16 in the blind hole structures may surround the solder hole 15 similarly, thereby forming a heat collecting area A at the solder hole 15 (indicated by A in FIG. 3).

FIG. 5 is a schematic sectional view according to still another embodiment of the present invention. The specific implementation is substantially the same as the embodiments above, and only the difference is illustrated in the following. In this embodiment, the heat collecting holes 16 are disposed in the middle of the board body 10 in a buried hole structure. In other words, the heat collecting holes 16 are formed in the hollow parts of the board body 10, and do not penetrate the upper and lower surfaces 11 and 12 of the board body 10 respectively. In such a manner, the heat collecting holes 16 in the buried hole structure may surround the solder hole 15, thereby forming a heat collecting area A at the solder hole 15 (indicated by A in FIG. 3).

Additionally, through the buried hole design of the heat collecting holes 16, when the solder 20 enters the solder hole 15, the heat (that is, the hot air) generated by the solder 20 infiltrates the inside of the heat collecting holes 16 in the buried hole structure in advance, and the heat (that is, the hot air) of the solder is kept in the heat collecting area A by the heat collecting holes 16, ensuring that the solder hole 15 stays at a stable high-temperature soldering state in the heat collecting area A, so as to prevent the problem that the solder 20 is solidified when rising within the solder hole 15.

The method for soldering electronic components of a circuit board and the circuit board structure thereof according to the present invention have the following effects: the at least one heat collecting hole is disposed on the circuit board in a penetrating or a non-penetrating manner, and the heat collecting holes surround the solder hole respectively; a heat collecting area is formed at the solder hole through the surrounding heat collecting holes. Thus, when the solder is filled in the solder hole, the heat of the solder may be kept in the heat collecting area by the heat collecting holes, and the heat collecting area keeps a stable heat in the inside of the solder hole, ensuring that the solder hole is filled with the solder, and that the solder is combined with the pin of the electronic component within the solder hole.

What is claimed is:

1. A method for soldering electronic components of a circuit board, comprising:
providing a circuit board, wherein the circuit board has a plurality of wire layers, and is disposed with at least one solder hole and at least one heat collecting hole, the solder hole and the wire layers are electrically conducted, the heat collecting hole is disposed around the solder hole to form a heat collecting area, and the heat collecting hole and the wire layers are non-electrically conducted;
disposing at least one electronic component on the circuit board, wherein at least one pin of the electronic component extends into the solder hole of the circuit board; and
performing a soldering process on the circuit board, so as to enable a solder to enter the solder hole, and keeping heat of the solder in the heat collecting area by the heat collecting hole, such that the pin of the electronic component within the solder hole is combined with the solder.

2. The method for soldering electronic components of a circuit board according to claim 1, wherein the forming the heat collecting hole around the solder hole further comprises: forming a plurality of the heat collecting holes, wherein the heat collecting holes surround the solder hole in a geometric arrangement.

3. The method for soldering electronic components of a circuit board according to claim 1, wherein the provided soldering process is a wave soldering process.

4. The method for soldering electronic components of a circuit board according to claim 1, wherein the disposing the heat collecting hole on the circuit board further comprises: forming the heat collecting hole on the circuit board in a penetrating manner or a non-penetrating manner.

5. A circuit board structure, formed by soldering a solder and at least one pin of at least one electronic component, comprising:
a board body, having a plurality of wire layers stacked with each other;
at least one solder hole, passing through the board body, and electrically conducted with the wire layers, wherein the pin of the electronic component extends into the solder hole; and
at least one heat collecting hole, disposed around the solder hole to form a heat collecting area, wherein the heat collecting hole and the wire layers are non-electrically conducted;
wherein the solder is disposed within the solder hole, heat of the solder is kept in the heat collecting area by the heat collecting hole, such that the pin of the electronic component is combined with the solder.

6. The circuit board structure according to claim 5, wherein the heat collecting hole is a through hole and passes through the board body.

7. The circuit board structure according to claim 5, wherein the heat collecting hole is a blind hole disposed at a side of the board body.

8. The circuit board structure according to claim 5, wherein the heat collecting hole is a buried hole disposed inside the board body.

9. The circuit board structure according to claim 5, wherein the solder hole further has a metal coating, and the metal coating is disposed on an internal surface of the solder hole and is electrically conducted with the wire layers.

10. The circuit board structure according to claim 5, further comprising a plurality of the heat collecting holes, wherein the heat collecting holes surround the solder hole in a geometric arrangement.
